(19) United States
(12) Patent Application Publication
(10) Pub. No.: US 2026/0156937 A1
(43) Pub. Date: Jun. 4, 2026

(54) SEMICONDUCTOR DEVICE, DISPLAY DEVICE, AND MANUFACTURING METHOD OF SEMICONDUCTOR DEVICE

(71) Applicant: Sharp Kabushiki Kaisha, Sakai City (JP)

(72) Inventors: Masahito SANO, Sakai City (JP); Seiji KANEKO, Sakai City (JP)

(21) Appl. No.: 19/399,863

(22) Filed: Nov. 25, 2025

(30) Foreign Application Priority Data
Dec. 3, 2024 (JP) 2024-210514

(51) Int. Cl. H10D 86/40; G02F 1/1368; H10D 86/01; H10D 86/60

(52) U.S. Cl. CPC H10D 86/423; G02F 1/1368; H10D 86/0221; H10D 86/60

(57) ABSTRACT

A semiconductor device includes a semiconductor portion, a first insulating film, a first conductive portion disposed not to overlap the semiconductor portion, a second insulating film, a second conductive portion overlapping the semiconductor portion, and a third conductive portion overlapping the first conductive portion, in which the first insulating film and the second insulating film are provided with a first contact hole overlapping both the semiconductor portion and the second conductive portion, the second insulating film is provided with a second contact hole overlapping both the first conductive portion and the third conductive portion, the first conductive portion includes at least a first conductive layer disposed on the first insulating film, a second conductive layer disposed on the first conductive film, and a sacrificial layer disposed on the second conductive film, and the sacrificial layer includes a communication hole communicating with the second contact hole.

### CROSS-REFERENCE TO RELATED APPLICATIONS

This application claims the benefit of priority to Japanese Patent Application Number 2024-210514 filed on Dec. 3, 2024. The entire contents of the above-identified application are hereby incorporated by reference.

### BACKGROUND

### Technical Field

The technology disclosed in the present specification relates to a semiconductor device, a display device, and a manufacturing method of a semiconductor device, in which a contact state between a semiconductor portion and a second conductive portion is maintained in a favorable manner.

A display panel described in US 2021/0335938 is known as an example of a semiconductor device in the related art. In the display panel disclosed in US 2021/0335938, a certain amount of the protection layer is etched in the first contact region and the second contact region of the active layer, so that the first via hole and the second via hole expose the surface of the active layer, and the source/drain metal layer is connected to the active layer through the first via hole and the second via hole. Since a hydrofluoric acid cleaning machine is not used for rinsing the protection layer, the first capacitor electrode and the second capacitor electrode are effectively prevented from being etched by hydrofluoric acid.

### SUMMARY

In the display panel described in US 2021/0335938, the inside of each of the first via hole and the second via hole is pre-cleaned by a pre-cleaning device including a UV exposure device and various cleaning units, and hydrofluoric acid cleaning using the hydrofluoric acid cleaning machine is not performed. Here, in a portion of the first contact region and the second contact region of the active layer, which is exposed through the first via hole and the second via hole, an oxide film is naturally formed with the passage of time, but the oxide film cannot be removed by the above-described pre-cleaning device. Thus, the contact state between the first contact region and the second contact region and the source/drain metal layer may be deteriorated due to the oxide film.

The technique described in the present specification has been made based on the circumstances described above, and is directed to making a contact state between a semiconductor portion and a second conductive portion to be maintained in a favorable manner.

(1) A semiconductor device according to a technology described in the present specification includes a semiconductor portion constituted of a part of a semiconductor film, a first insulating film disposed on an upper-layer side of the semiconductor film, a first conductive portion disposed on an upper-layer side of the first insulating film and disposed not to overlap the semiconductor portion, a second insulating film disposed on an upper-layer side of the first insulating film and the first conductive portion, a second conductive portion disposed on an upper-layer side of the second insulating film and disposed to overlap the semiconductor portion, and a third conductive portion disposed on an upper-layer side of the second insulating film and disposed to overlap the first conductive portion, in which the first insulating film and the second insulating film are provided with a first contact hole disposed to overlap both the semiconductor portion and the second conductive portion, the second insulating film is provided with a second contact hole disposed to overlap both the first conductive portion and the third conductive portion, the first conductive portion includes at least a first conductive layer constituted of a part of the first conductive film disposed on the upper-layer side of the first insulating film, a second conductive layer constituted of a part of the second conductive film disposed on the upper-layer side of the first conductive film, and a sacrificial layer constituted of a part of a sacrificial film disposed on an upper-layer side of the second conductive film, and the sacrificial layer is made of a semiconductor material or a conductive material, and includes a communication hole communicating with the second contact hole.

(2) In addition to the above (1), in the semiconductor device, the sacrificial layer may be made of an oxide semiconductor material that is the semiconductor material.

(3) In addition to the above (1) or (2), in the semiconductor device, the sacrificial layer may be made of a transparent electrode material that is the conductive material.

(4) In addition to any one of the above (1) to (3), in the semiconductor device, the first conductive layer may include aluminum, and the second conductive layer may include molybdenum.

(5) In addition to any of the above (1) to (4), in the semiconductor device, a film thickness of the sacrificial layer may be equal to 40 nm or less.

(6) A display device according to a technology described in the present specification includes the semiconductor device according to any one of the above (1) to (5) and a counter substrate disposed to face the semiconductor device.

(7) A manufacturing method of a semiconductor device according to the technology described in the present specification includes forming a semiconductor film, and patterning the formed semiconductor film to provide a semiconductor portion, forming a first insulating film on an upper-layer side of the semiconductor film, forming a first conductive portion including, in order from a lower-layer side, at least a first conductive layer constituted of a part of a first conductive film, a second conductive layer constituted of a part of a second conductive film, and a sacrificial layer constituted of a part of a sacrificial film at a position not overlapping the semiconductor portion by sequentially forming at least the first conductive film, the second conductive film, and the sacrificial film made of a semiconductor material or a conductive material each on an upper-layer side of the first insulating film and patterning the first conductive film, the second conductive film, and the sacrificial film, forming a second insulating film on an upper-layer side of the first insulating film and the first conductive portion, providing a part of a first contact hole at a position overlapping the semiconductor portion and a second contact hole at a position overlapping the first conductive portion by patterning the second insulating film, providing a remaining portion of the first contact hole by patterning the first insulating film following the second insulating film, cleaning a portion of the semiconductor portion facing the first contact hole and providing a communication hole communicating with the second contact hole in the sacrificial layer of the first conductive portion, by supplying a cleaning agent including hydrofluoric acid to the inside of the first contact hole and the second contact hole, providing a second conductive portion on an upper-layer side of the second insulating film at a position overlapping the semiconductor portion, and connecting the second conductive portion to the semiconductor portion through the first contact hole, and providing a third conductive portion on an upper-layer side of the second insulating film at a position overlapping the first conductive portion, and connecting the third conductive portion to the second conductive layer of the first conductive portion through the second contact hole and the communication hole.

(8) In addition to the above (7), in the manufacturing method of a semiconductor device, the sacrificial film made of an oxide semiconductor material that is the semiconductor material may be formed, and an annealing process may be performed after the first conductive portion is provided.

According to the technology described in the present specification, a contact state between a semiconductor portion and a second conductive portion can be maintained in a favorable manner.

### BRIEF DESCRIPTION OF DRAWINGS

The disclosure will be described with reference to the accompanying drawings, wherein like numbers reference like elements.

FIG. 1 is a plan view of a liquid crystal panel, a driver, and a flexible substrate according to a first embodiment.

FIG. 2 is a cross-sectional view of the liquid crystal panel, the driver, and the flexible substrate according to the first embodiment.

FIG. 3 is a plan view illustrating a pixel arrangement of the liquid crystal panel according to the first embodiment.

FIG. 4 is a plan view illustrating a part of a gate circuit portion provided in an array substrate according to the first embodiment.

FIG. 5 is a cross-sectional view of the array substrate according to the first embodiment, taken along a line v-v in FIG. 4.

FIG. 6 is a cross-sectional view similar to FIG. 5, illustrating a state where, in a first step included in a manufacturing method of the array substrate according to the first embodiment, a base coat film is formed, and in a subsequent second step, a semiconductor film is formed.

FIG. 7 is a cross-sectional view similar to FIG. 5, illustrating a state where a first photoresist pattern is formed in the second step included in the manufacturing method of an array substrate according to the first embodiment.

FIG. 8 is a cross-sectional view similar to FIG. 5, illustrating a state where a gate constituent film is formed in a fourth step after a gate insulating film is formed in a third step included in the manufacturing method of an array substrate according to the first embodiment.

FIG. 9 is a cross-sectional view similar to FIG. 5, illustrating a state where a second photoresist pattern is formed in the fourth step included in the manufacturing method of an array substrate according to the first embodiment.

FIG. 10 is a cross-sectional view similar to FIG. 5, illustrating a state where the gate constituent film is etched with the second photoresist pattern as a mask in the fourth step included in the manufacturing method of an array substrate according to the first embodiment.

FIG. 11 is a cross-sectional view similar to FIG. 5, illustrating a state where an interlayer insulating film is formed, in a sixth step after a fifth step included in the manufacturing method of an array substrate according to the first embodiment.

FIG. 12 is a cross-sectional view similar to FIG. 5, illustrating a state where a third photoresist pattern is formed in the sixth step included in the manufacturing method of an array substrate according to the first embodiment.

FIG. 13 is a cross-sectional view similar to FIG. 5, illustrating a state where the interlayer insulating film and the gate constituent film are etched with the third photoresist pattern as a mask in the sixth step included in the manufacturing method of an array substrate according to the first embodiment.

FIG. 14 is a cross-sectional view similar to FIG. 5, illustrating a state where a cleaning liquid is supplied onto the interlayer insulating film and a communication hole is formed in the sacrificial layer in a seventh step included in the manufacturing method of an array substrate according to the first embodiment

FIG. 15 is a cross-sectional view similar to FIG. 5, illustrating a state where a fourth metal film is formed in an eighth step included in the manufacturing method of an array substrate according to the first embodiment.

FIG. 16 is a cross-sectional view similar to FIG. 5, illustrating a state where a fourth photoresist pattern is formed in the eighth step included in the manufacturing method of an array substrate according to the first embodiment.

### DESCRIPTION OF EMBODIMENTS

### First Embodiment

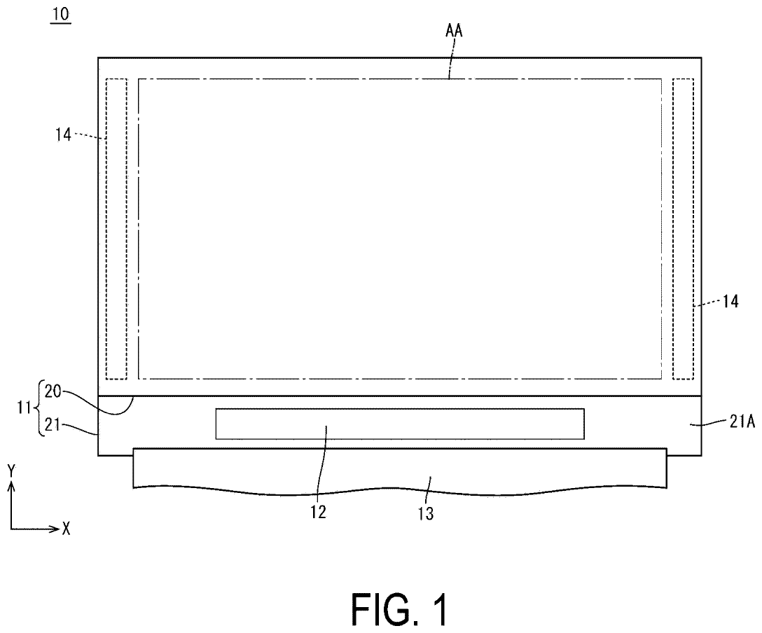

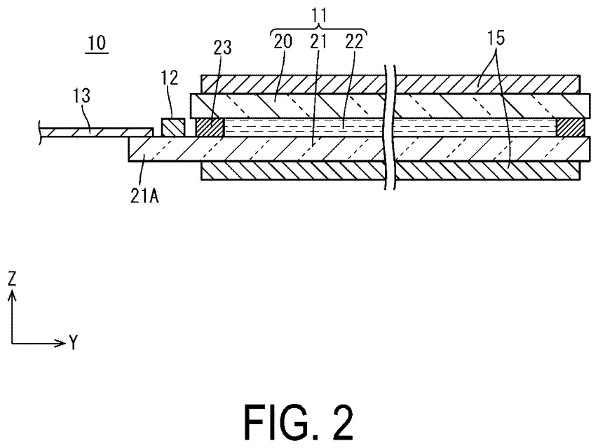

A first embodiment will be described with reference to FIGS. 1 to 16. In present embodiment, a liquid crystal display device 10 is exemplified. Note that some drawings illustrate an X-axis, a Y-axis, and a Z-axis, and directions of these axes are drawn so as to be common in all the drawings. In addition, an upper side and a lower side in each of FIG. 2, and 5 to 16 are respectively defined as a front side and a rear side.

The liquid crystal display device 10, as illustrated in FIG. 1, includes at least a liquid crystal panel (display device, display panel) 11 that has a horizontally elongated rectangular shape and is capable of displaying an image, and a backlight device (illumination device) that irradiates the liquid crystal panel 11 with light for use in display. The backlight device includes a light source (for example, an LED or the like) disposed on a rear side (back face side) of the liquid crystal panel 11 and configured to emit light having a white color, an optical member configured to impart an optical effect on the light from the light source, thereby converting the light into planar light, and the like. A center-side portion of a main surface of the liquid crystal panel 11 is a display region AA in which an image is displayed. In contrast, a frame-shaped outer peripheral portion surrounding the display region AA of the main surface of the liquid crystal panel 11 is a non-display region NAA in which no image is displayed.

As illustrated in FIG. 1, a gate circuit portion 14 is provided in the non-display region NAA of the liquid crystal panel 11. A pair of gate circuit portions 14 are disposed to sandwich the display region AA from both sides thereof in the X-axis direction. The gate circuit portions 14 are provided in a belt-shaped range extending in the Y-axis direction. The gate circuit portions 14 are configured to supply a scanning signal to a gate wiring line 26 to be described later, and are monolithically provided on an array substrate 21 to be described later. The gate circuit portion 14 is a gate driver monolithic (GDM) circuit. The gate circuit portion 14 includes a shift register circuit configured to output a scanning signal at a predetermined timing, a buffer circuit for amplifying the scanning signal, and the like.

The liquid crystal panel 11 will be described with reference to FIG. 2 in addition to FIG. 1. As illustrated in FIGS. 1 and 2, the liquid crystal panel 11 is formed by bonding a pair of substrates 20 and 21 together. Of the pair of substrates 20, 21, the substrate on a front side is a counter substrate 20, and the substrate on a rear side is an array substrate (semiconductor device) 21. The counter substrate 20 and the array substrate 21 are each formed by layering various films on an inner face side of a glass substrate. A liquid crystal layer 22 is interposed between the pair of substrates 20, 21 and contains liquid crystal molecules, which are substances having optical characteristics that change in accordance with application of an electrical field. A sealing portion 23 that seals the liquid crystal layer 22 is provided to be interposed between outer peripheral ends of the pair of substrates 20 and 21. The sealing portion 23 is formed in a rectangular frame-like shape to surround the liquid crystal layer 22. Polarizers 15 are bonded to the outer face sides of both the substrates 20 and 21, respectively.

As illustrated in FIG. 1 and FIG. 2, the counter substrate 20 has a short side dimension shorter than a short side dimension of the array substrate 21. The counter substrate 20 is bonded to the array substrate 21 with one end in a short side direction (Y-axis direction) aligned with the array substrate 21. Thus, the other end of the array substrate 21 in the short side direction is an exposed portion 21A that protrudes laterally relative to the counter substrate 20 and is exposed. An overall region of this exposed portion 21A is a non-display region NAA, in which a driver 12 for supplying various signals and a flexible substrate 13 are mounted.

The driver 12 includes an LSI chip having a drive circuit therein. The driver 12 is mounted on the exposed portion 21A of the array substrate 21 in a chip-on-glass (COG) manner. The driver 12 processes various signals transmitted by the flexible substrate 13. As illustrated in FIG. 1 and FIG. 2, the driver 12 is adjacent to one side of the display region AA in the Y-axis direction, and is sandwiched between the flexible substrate 13 to be described below and the display region AA. The driver 12 has a horizontally elongated rectangular planar shape. The driver 12 can supply various signals to a source wiring line 27 and the like provided on the array substrate 21. The flexible substrate 13 has a configuration in which a large number of wiring line patterns are formed on a base material made of a synthetic resin material (for example, a polyimide resin or the like) having insulating properties and flexibility. One end of the flexible substrate 13 is connected to the exposed portion 21A of the array substrate 21, and the other end is connected to an external circuit substrate (a control substrate or the like).

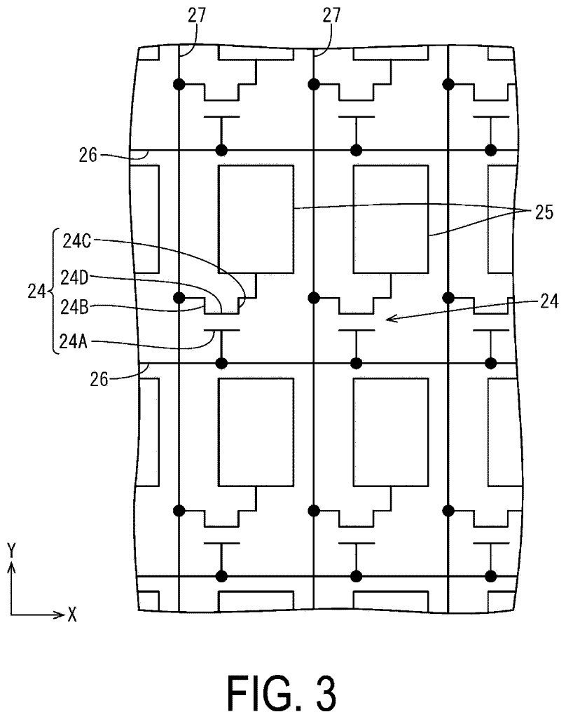

Next, a configuration of the display region AA in the array substrate 21 will be described with reference to FIG. 3. As illustrated in FIG. 3, at least a pixel TFT (pixel transistor, pixel switching element) 24 and a pixel electrode 25 are provided on an inner face side of the display region AA of the array substrate 21. The plurality of pixel TFTs 24 and the plurality of pixel electrodes 25 are provided side by side in a matrix at intervals in the X-axis direction and the Y-axis direction. Gate wiring lines (scanning wiring lines) 26 and source wiring lines (image wiring lines, signal wiring lines) 27 orthogonal to (intersecting) each other are disposed around the pixel TFTs 24 and the pixel electrodes 25. The gate wiring lines 26 extend along the X-axis direction and a plurality of the gate wiring lines 26 are disposed at intervals in the Y-axis direction. The source wiring lines 27 extend along the Y-axis direction and a plurality of the source wiring lines 27 are disposed at intervals in the X-axis direction.

As illustrated in FIG. 3, the pixel TFT 24 includes a pixel gate electrode 24A connected to the gate wiring line 26, a pixel source electrode 24B connected to the source wiring line 27, a pixel drain electrode 24C connected to the pixel electrode 25, and a pixel semiconductor portion 24D connected to the source electrode 24B and drain electrode 24C and made of a semiconductor material. The pixel TFT 24 is driven on the basis of a scanning signal supplied to the pixel gate electrode 24A by the gate wiring line 26. The scanning signal includes a potential higher than the threshold voltage of the pixel TFT 24. Then, a channel region is generated in the pixel semiconductor portion 24D, so that charges can move between the pixel source electrode 24B and the pixel drain electrode 24C through the channel region. Thus, a potential of an image signal (data signal) supplied to the pixel source electrode 24B through the source wiring line 27 is supplied to the pixel drain electrode 24C through the pixel semiconductor portion 24D. As a result, the pixel electrode 25 is charged to the potential related to the image signal. The pixel electrode 25 is made of a transparent electrode material, and has a vertically long, substantially rectangular planar shape, for example. The pixel electrode 25 is disposed in a region surrounded by two gate wiring lines 26 adjacent to each other and spaced apart in the Y-axis direction and two source wiring lines 27 adjacent to each other and spaced apart in the X-axis direction.

Further, in the display region AA of the counter substrate 20, multiple color filters are provided at positions facing each of the pixel electrodes 25 on the array substrate 21 side. As for the color filters, three colors, namely, R (red), G (green), and B (blue) are repeatedly disposed side by side in a predetermined order, and each pixel (red pixel, green pixel and blue pixel) is constituted together with the pixel electrode 25. A display pixel capable of color display with a predetermined gray scale is constituted by three pixels of the red pixel, the green pixel, and the blue pixel. In the display region AA of the counter substrate 20, a light blocking portion (black matrix) for preventing color mixing is formed between the respective color filters. In addition, either the counter substrate 20 or the array substrate 21 is provided with a common electrode made of the same transparent electrode material as that of the pixel electrode 25 and disposed to overlap the pixel electrode 25 with a gap therebetween. In the liquid crystal panel 11, a predetermined electrical field is applied to the liquid crystal layer 22 on the basis of a potential difference generated between the common electrode and each pixel electrode 25, thereby enabling each pixel to display a predetermined gradation. Note that alignment films (not illustrated) for aligning the liquid crystal molecules included in the liquid crystal layer 22 are respectively formed on innermost faces (uppermost layers) in contact with the liquid crystal layer 22 of both the substrates 20, 21.

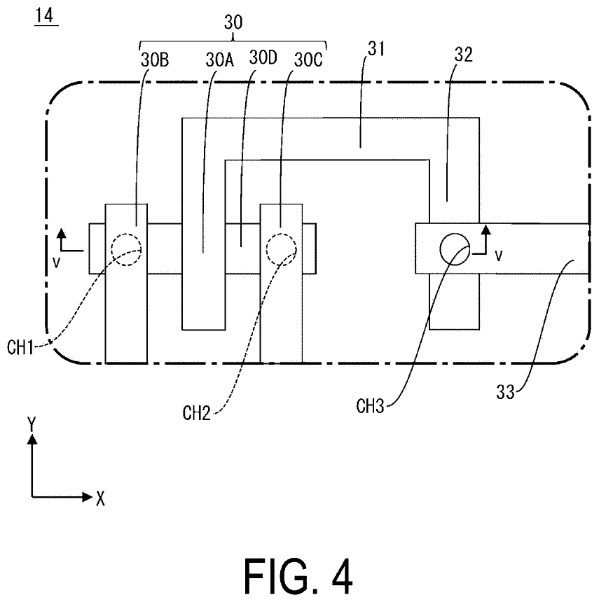

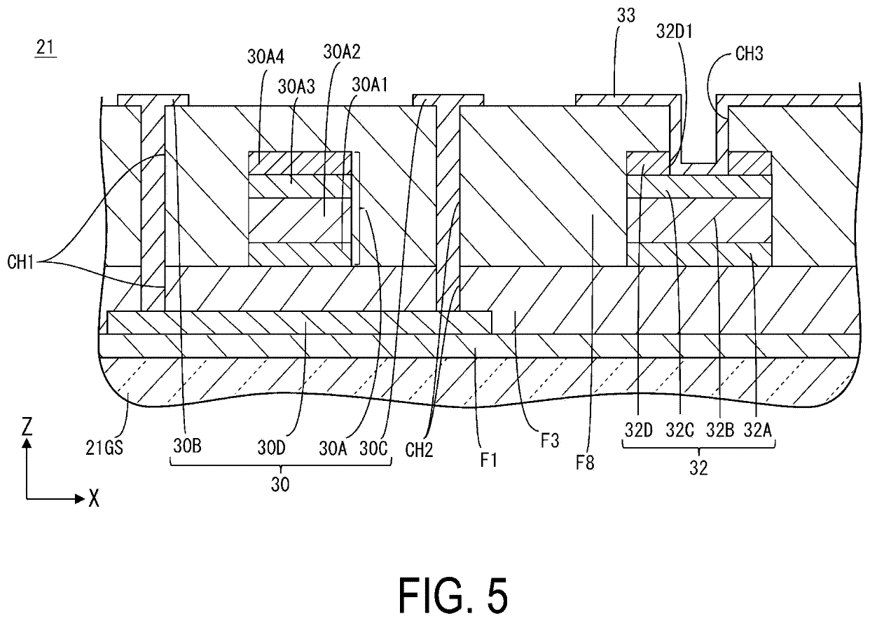

Next, a configuration of the non-display region NAA in the array substrate 21 will be described with reference to FIGS. 4 and 5. The gate circuit portion 14 provided in the non-display region NAA of the array substrate 21 is provided with various circuit elements including at least a non-pixel transistor (non-pixel TFT, a non-pixel switching element) 30. Furthermore, the circuit elements of the gate circuit portion 14 include at least a drive wiring line (third conductive portion) 33 that transmits a drive signal for driving the non-pixel TFT 30, and a connection wiring line 31 and a connection electrode (first conductive portion) 32 for connecting the non-pixel TFT 30 and the drive wiring line 33 to each other.

The non-pixel TFT 30 is of a so-called top-gate type. The pixel TFT 24 is also of the top gate type, similar to the non-pixel TFT 30. As illustrated in FIG. 4, the non-pixel TFT 30 includes a non-pixel gate electrode 30A, a non-pixel source electrode (second conductive portion) 30B, a non-pixel drain electrode (second conductive portion) 30C, and a non-pixel semiconductor portion (semiconductor portion) 30D. The non-pixel gate electrode 30A included in the non-pixel TFT 30 extends along the Y-axis direction, and includes one end (lower side in FIG. 4) disposed to overlap the non-pixel semiconductor portion 30D. The non-pixel gate electrode 30A includes the other end (upper side in FIG. 4) connected to the connection wiring line 31 described later. As will be described in detail later, the non-pixel gate electrode 30A is supplied with a drive signal from the drive wiring line 33 via the connection wiring line 31 and the connection electrode 32. The non-pixel source electrode 30B provided in the non-pixel TFT 30 is disposed at a position spaced apart from the non-pixel gate electrode 30A in the X-axis direction on one side (left side in FIG. 4). The non-pixel source electrode 30B extends along the Y-axis direction, and includes one end (upper side in FIG. 4) disposed to overlap the non-pixel semiconductor portion 30D. The non-pixel source electrode 30B includes the other end (lower side in FIG. 4) extending to the outside of the non-pixel semiconductor portion 30D, connected to a wiring line (not illustrated) provided in the gate circuit portion 14, and supplied with a predetermined signal from the wiring line.

As illustrated in FIG. 4, the non-pixel drain electrode 30C provided in the non-pixel TFT 30 is disposed at a position spaced apart from the non-pixel gate electrode 30A in the X-axis direction on the other end side (right side in FIG. 4). The non-pixel drain electrode 30C extends along the Y-axis direction, and includes one end (upper side in FIG. 4) disposed to overlap the non-pixel semiconductor portion 30D. The non-pixel drain electrode 30C includes the other end (lower side in FIG. 4) extending to the outside of the non-pixel semiconductor portion 30D and connected to a wiring line (not illustrated) provided in the gate circuit portion 14, so that a signal from the non-pixel source electrode 30B can be output to the wiring line. The non-pixel semiconductor portion 30D constituting the non-pixel TFT 30 has a horizontally elongated rectangular shape in a plan view. The non-pixel gate electrode 30A is disposed to overlap a central portion of the non-pixel semiconductor portion 30D in the X-axis direction. The non-pixel source electrode 30B is disposed to overlap one end side (left side in FIG. 4) portion of the non-pixel semiconductor portion 30D in the X-axis direction. The non-pixel drain electrode 30C is disposed to overlap the other end side (right side in FIG. 4) portion of the non-pixel semiconductor portion 30D in the X-axis direction.

In the non-pixel TFT 30 having the above-described configuration, when a voltage equal to the threshold voltage or more is applied to the non-pixel gate electrode 30A, a channel region is generated in a portion (a non-reduced resistance region described later) of the non-pixel semiconductor portion 30D overlapping the non-pixel gate electrode 30A. Then, charges can move between the non-pixel source electrode 30B and the non-pixel drain electrode 30C through the channel region of the non-pixel semiconductor portion 30D. Thus, the signal supplied to the non-pixel source electrode 30B can be transmitted to the non-pixel drain electrode 30C.

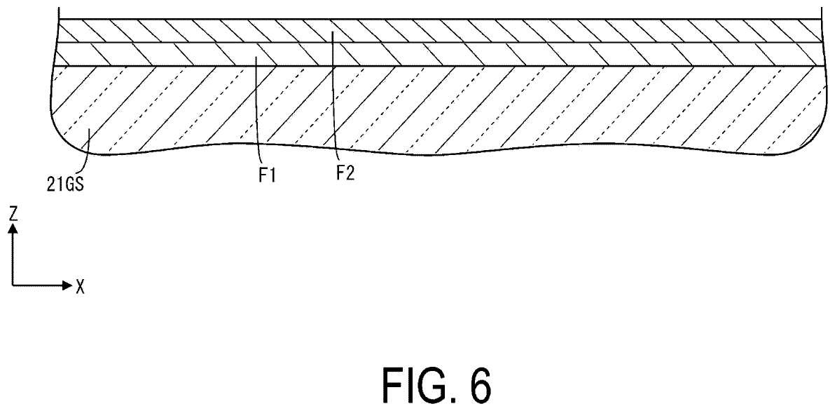

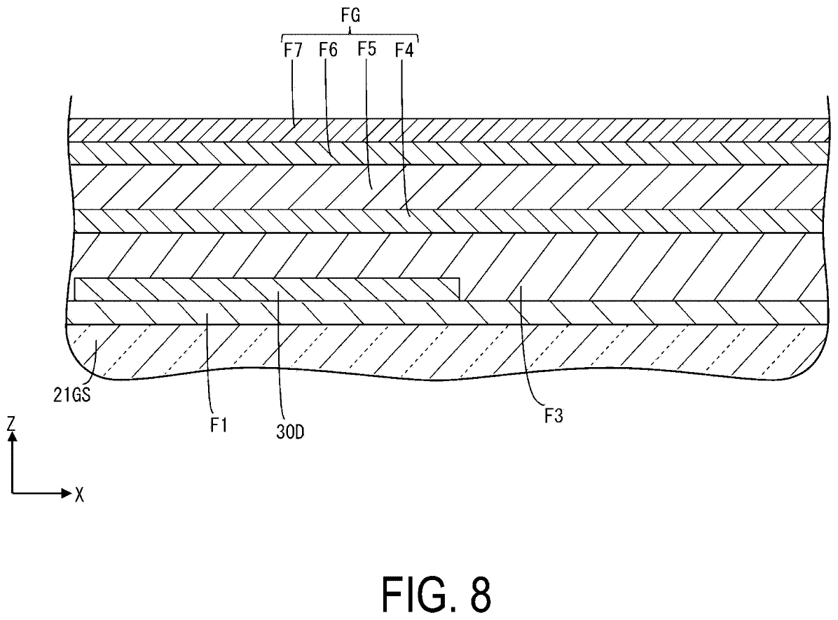

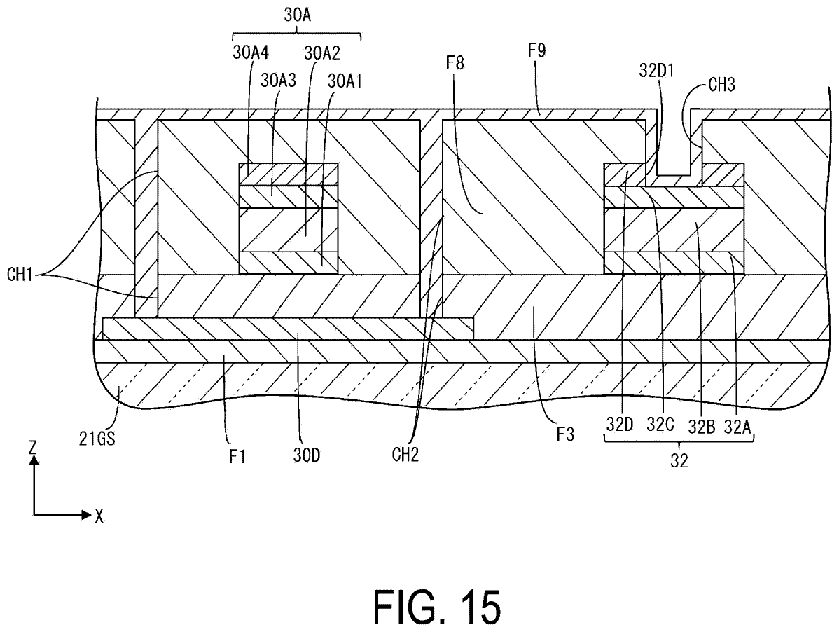

Next, various films layered on the glass substrate (substrate) 21GS of the array substrate 21 will be described in detail with reference to FIG. 5. As illustrated in FIG. 5, in order from the lower-layer side (glass substrate 21GS side), at least a base coat film F1, a semiconductor film F2, a gate insulating film (first insulating film) F3, a first metal film F4, a second metal film (first conductive film) F5, a third metal film (second conductive film) F6, a sacrificial film F7, an interlayer insulating film (second insulating film) F8, and a fourth metal film F9, are formed to be layered on the glass substrate 21GS of the array substrate 21. The semiconductor film F2 is illustrated in FIG. 6, the first metal film F4, the second metal film F5, the third metal film F6, and the sacrificial film F7 (gate constituent film FG described later) are illustrated in FIG. 8, and the fourth metal film F9 is illustrated in FIG. 15. Other than the above-described films, a transparent electrode film constituting the pixel electrode 25, an alignment film for aligning liquid crystal molecules, and the like are formed on the glass substrate 21GS of the array substrate 21.

Each structure provided in the display region AA and the non-display region NAA of the array substrate 21 is made of any one of the films F1 to F9 (including the transparent electrode film, the alignment film, and the like). Specifically, in the display region AA, among the above-described films F1 to F9, the first metal film F4, the second metal film F5, the third metal film F6, and the sacrificial film F7 constitute the gate wiring line 26, the pixel gate electrode 24A and the like (see FIG. 3). Hereinafter, a layered film of four layers including the first metal film F4, the second metal film F5, the third metal film F6, and the sacrificial film F7 is referred to as a “gate constituent film”, and “FG” is added to the reference numeral thereof. As illustrated in FIG. 5, in the non-display region NAA, the gate constituent film FG constitutes the non-pixel gate electrode 30A, the connection wiring line 31, the connection electrode 32, and the like. The first metal film F4 is a single-layer film made of one kind of a metal material, and is made of, for example, molybdenum (Mo). The first metal film F4 has a thickness of, for example, about 20 nm. By disposing the first metal film F4 made of Mo on the lower-layer side of the second metal film F5, the adhesion of the gate constituent film FG to the gate insulating film F3 that is the base of the gate constituent film FG becomes favorable.

The second metal film F5 is a single-layer film made of one kind of a metal material, and is made of, for example, aluminum (Al). In the present embodiment, the material of the second metal film F5 is Al, and thus a wiring line resistance of the gate wiring line 26 can be reduced as compared with the case where tantalum (Ta) or tungsten (W) is used. A film thickness of the second metal film F5 is larger than the film thickness of the first metal film F4, and is, for example, 300 nm or more. As a result, the wiring line resistance of the gate wiring line 26 can be further reduced. The third metal film F6 is a single-layer film made of one kind of a metal material, and is made of, for example, Mo. The third metal film F6 made of Mo has higher tolerability to hydrofluoric acid than the second metal film F5 made of Al. A film thickness of the third metal film F6 is smaller than the film thickness of the second metal film F5, and is, for example, about 20 nm. The sacrificial film F7 is a single-layer film made of a semiconductor material or a transparent electrode material, and is made of any one of, for example, an In—Ga—Zn—O-based semiconductor material (for example, indium gallium zinc oxide), an In—Sn—Zn—O-based semiconductor material (for example, indium tin zinc oxide), and an In—Ga—O-based semiconductor material (for example, indium gallium oxide), which are the oxide semiconductor materials, and indium zinc oxide (IZO) that is a transparent electrode material. The sacrificial film F7 made of the semiconductor material or the transparent electrode material has higher tolerability to etching (particularly, dry etching) than the third metal film F6 made of Mo. On the other hand, the sacrificial film F7 made of the semiconductor material or the transparent electrode material has lower tolerability to hydrofluoric acid than the third metal film F6 made of Mo. The film thickness of the sacrificial film F7 is, for example, equal to 10 nm or more and equal to 40 nm or less.

In the display region AA, the fourth metal film F9 constitutes the source wiring line 27, the pixel source electrode 24B, the pixel drain electrode 24C, and the like (see FIG. 3). Hereinafter, the fourth metal film F9 is referred to as a “source constituent film”. As illustrated in FIG. 5, in the non-display region NAA, the source constituent film (fourth metal film F9) constitutes the non-pixel source electrode 30B, the non-pixel drain electrode 30C, the drive wiring line 33, and the like.

In the display region AA, the semiconductor film F2 constitutes the pixel semiconductor portion 24D and the like (see FIG. 3). As illustrated in FIG. 5, in the non-display region NAA, the semiconductor film F2 constitutes the non-pixel semiconductor portion 30D and the like. The semiconductor film F2 is made of a polysilicon semiconductor material (semiconductor material) having crystalline formed by a known method such as laser crystallization. The film thickness of the semiconductor film F2 is, for example, about 50 nm. The polysilicon semiconductor material of the semiconductor film F2 has higher electron mobility than an amorphous silicon semiconductor material and an oxide semiconductor material. The pixel semiconductor portion 24D and the non-pixel semiconductor portion 30D, which are formed by portions of the semiconductor film F2, are subjected to a reduced resistance process (conductorization process) by using the pixel gate electrode 24A and the non-pixel gate electrode 30A, respectively, as masks in the manufacturing process of the array substrate 21. By performing the reduced resistance process, portions of the pixel semiconductor portion 24D and the non-pixel semiconductor portion 30D not overlapping the pixel gate electrode 24A and the non-pixel gate electrode 30A, respectively, become the reduced resistance (made conductive). The reduced resistance process includes a doping process using an ion species such as boron (B) or phosphorus (P), an annealing process, and the like. The non-pixel source electrode 30B and the non-pixel drain electrode 30C are connected to a reduced resistance portion (reduced resistance region) of the non-pixel semiconductor portion 30D. The pixel source electrode 24B and the pixel drain electrode 24C are connected to a reduced resistance portion (reduced resistance region) of the pixel semiconductor portion 24D (see FIG. 3). A portion (non-reduced resistance region) of the non-pixel semiconductor portion 30D overlapping the non-pixel gate electrode 30A, is not reduced in the resistance, and the charge can move only under a specific condition (when the drive signal is supplied to the non-pixel gate electrode 30A). Similarly, a portion (non-reduced resistance region) of the pixel semiconductor portion 24D overlapping the pixel gate electrode 24A, is not reduced in the resistance, the charge can move only under a specific condition (when the drive signal is supplied to the pixel gate electrode 24A).

The base coat film F1, the gate insulating film F3, and the interlayer insulating film F8 are all single-layer films or a layered film made of an inorganic material (inorganic resin material), such as silicon oxide (SiO₂) or silicon nitride (SiNₓ). The base coat film F1 is a base of the semiconductor film F2, and can prevent an impurity from the glass substrate 21GS constituting the array substrate 21 from diffusing to the semiconductor film F2. The gate insulating film F3 is interposed between the semiconductor film F2 and the gate constituent film FG (the first metal film F4 as the lowermost layer) to keep them in a state of being insulated from each other. Specifically, as illustrated in FIG. 5, in the non-display region NAA, the gate insulating film F3 keeps the non-pixel semiconductor portion 30D and the non-pixel gate electrode 30A in a state of being insulated from each other. In the display region AA, the gate insulating film F3 keeps the pixel semiconductor portion 24D and the pixel gate electrode 24A in a state of being insulated from each other (see FIG. 3). The interlayer insulating film F8 is interposed between the gate constituent film (the sacrificial film F7 as the uppermost layer) FG and the source constituent film (the fourth metal film F9), and keeps them in a state of being insulated from each other. Specifically, in the non-display region NAA, the interlayer insulating film F8 keeps the non-pixel gate electrode 30A, the non-pixel source electrode 30B, and the non-pixel drain electrode 30C in a state of being insulated from each other. In the display region AA, the interlayer insulating film F8 keeps the pixel gate electrode 24A, the pixel source electrode 24B, and the pixel drain electrode 24C in a state of being insulated from each other (see FIG. 3).

In the non-display region NAA of the array substrate 21, as illustrated in FIGS. 4 and 5, a non-pixel source contact hole (first contact hole) CH1 is provided in a communicating manner at a position of the gate insulating film F3 and the interlayer insulating film F8 overlapping both the non-pixel source electrode 30B and the non-pixel semiconductor portion 30D. The non-pixel source electrode 30B is connected to one end side portion (reduced resistance region) of the non-pixel semiconductor portion 30D through the non-pixel source contact hole CH1 of the gate insulating film F3 and the interlayer insulating film F8. Similarly, in the non-display region NAA of the array substrate 21, a non-pixel drain contact hole (first contact hole) CH2 is provided in a communicating manner at a position of the gate insulating film F3 and the interlayer insulating film F8 overlapping both the non-pixel drain electrode 30C and the non-pixel semiconductor portion 30D. The non-pixel drain electrode 30C is connected to the other end side portion (reduced resistance region) of the non-pixel semiconductor portion 30D through the non-pixel drain contact hole CH2 of the gate insulating film F3 and the interlayer insulating film F8. In the display region AA of the array substrate 21, a pixel source contact hole and a pixel drain contact hole are provided in a communicating manner at a position of the gate insulating film F3 and the interlayer insulating film F8 overlapping both the pixel source electrode 24B and the pixel semiconductor portion 24D and a position of the gate insulating film F3 and the interlayer insulating film F8 overlapping both the pixel drain electrode 24C and the pixel semiconductor portion 24D, respectively (see FIG. 3). The pixel source electrode 24B is connected to one of the reduced resistance regions of the pixel semiconductor portion 24D through the pixel source contact hole of the gate insulating film F3 and the interlayer insulating film F8, and the pixel drain electrode 24C is connected to the other of the reduced resistance regions of the pixel semiconductor portion 24D through the pixel drain contact hole of the gate insulating film F3 and the interlayer insulating film F8.

Next, a detailed configuration of the connection wiring line 31, the connection electrode 32, and the drive wiring line 33 will be described below. As illustrated in FIG. 4, the connection wiring line 31 extends along the X-axis direction, and includes one end (left side in FIG. 4) connected to the non-pixel gate electrode 30A. Similar to the non-pixel gate electrode 30A, the connection wiring line 31 is constituted of a part of the gate constituent film FG, and thus the connection wiring line 31 is directly connected to the gate constituent film FG to achieve a conductive connection. The connection wiring line 31 includes the other end (right side in FIG. 4) connected to the connection electrode 32. The connection electrode 32 extends from the other end of the connection wiring line 31 toward the same side (lower side in FIG. 4) as the non-pixel gate electrode 30A along the Y-axis direction, and has a vertically elongated rectangular shape in a plan view. Similar to the connection wiring line 31, the connection electrode 32 is constituted of a part of the gate constituent film FG, and thus the connection electrode 32 is directly connected to the connection wiring line 31 to achieve a conductive connection.

As illustrated in FIG. 4, the drive wiring line 33 extends along the X-axis direction, and includes one end (left side in FIG. 4) disposed to overlap the connection electrode 32. The drive wiring line 33 transmits the drive signal for driving the non-pixel TFT 30. The drive signal includes a potential higher than the threshold voltage of the non-pixel TFT 30. The drive wiring line 33 is constituted of a part of the fourth metal film F9 (source constituent film). Thus, the interlayer insulating film F8 is interposed between the drive wiring line 33 and the connection electrode 32 overlapping the drive wiring line 33. As illustrated in FIG. 5, a drive wiring line contact hole (second contact hole) CH3 is provided in a communicating manner at a position of the interlayer insulating film F8 interposed between the connection electrode 32 and the drive wiring line 33 overlapping each other overlapping both the connection electrode 32 and the drive wiring line 33. One end of the drive wiring line 33 is connected to the connection electrode 32 through the drive wiring line contact hole CH3 of the interlayer insulating film F8. Thus, the drive wiring line 33 is electrically connected to the non-pixel gate electrode 30A via the connection wiring line 31 and the connection electrode 32, and can supply the drive signal.

As illustrated in FIG. 5, the connection electrode 32 is constituted of a part of the gate constituent film FG and has a four-layer structure. Specifically, the connection electrode 32 includes, in order from the lower-layer side, a first metal layer 32A constituted of a part of the first metal film F4, a second metal layer (first conductive layer) 32B constituted of a part of the second metal film F5, a third metal layer (second conductive layer) 32C constituted of a part of the third metal film F6, and a sacrificial layer 32D constituted of a part of the sacrificial film F7. The sacrificial layer 32D located as the uppermost layer in the connection electrode 32 includes a communication hole 32D1 communicating with the drive wiring line contact hole CH3 of the interlayer insulating film F8. Thus, the drive wiring line 33 is in contact with the third metal layer 32C of the connection electrode 32 through the drive wiring line contact hole CH3 of the interlayer insulating film F8 and the communication hole 32D1 of the sacrificial layer 32D.

As described above, as illustrated in FIG. 5, the connection electrode 32 includes, in order from the lower-layer side, at least the first metal layer 32A, the second metal layer 32B, the third metal layer 32C, and the sacrificial layer 32D, and the sacrificial layer 32D is made of a semiconductor material or a conductive material. The sacrificial layer 32D made of the semiconductor material or the conductive material has higher tolerability to etching than the third metal layer 32C made of Mo. Thus, in the manufacturing process of the array substrate 21, when the non-pixel source contact hole CH1 and the non-pixel drain contact hole CH2 are provided by etching the gate insulating film F3 and the interlayer insulating film F8, and the drive wiring line contact hole CH3 is provided by etching the interlayer insulating film F8, the sacrificial layer 32D located as the uppermost layer of the connection electrode 32 is sacrificed, and the third metal layer 32C is less likely to be affected by the etching. That is, a situation in which the first metal layer 32A, the second metal layer 32B, and the third metal layer 32C (particularly, the third metal layer 32C) each located on the lower-layer side of the sacrificial layer 32D are over-etched can be made less likely to occur.

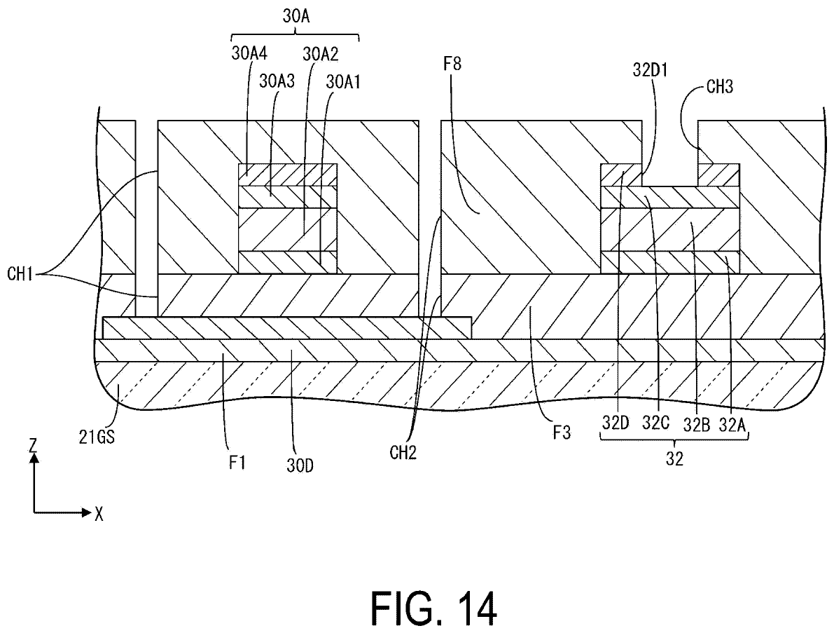

In the manufacturing process of the array substrate 21, when a cleaning agent containing, for example, hydrofluoric acid is supplied to the non-pixel source contact hole CH1 and the non-pixel drain contact hole CH2 each provided in the gate insulating film F3 and the interlayer insulating film F8, the surface of the non-pixel semiconductor portion 30D exposed through the non-pixel source contact hole CH1 and the non-pixel drain contact hole CH2 can be cleaned (see FIG. 14). At this time, the cleaning agent is also supplied to the drive wiring line contact hole CH3 provided in the interlayer insulating film F8. Here, the sacrificial layer 32D made of the semiconductor material or the conductive material has lower tolerability to hydrofluoric acid than the third metal layer 32C made of Mo, and thus when the cleaning agent is supplied to the drive wiring line contact hole CH3, the sacrificial layer 32D exposed through the drive wiring line contact hole CH3 is likely to be eluted into the cleaning agent. Accordingly, the communication hole 32D1 communicating with the drive wiring line contact hole CH3 is provided in the sacrificial layer 32D with high reliability. On the other hand, the third metal layer 32C made of Mo has higher tolerability to hydrofluoric acid than the sacrificial layer 32D, and thus is less likely to be eroded by the cleaning agent and is more likely to remain. Thus, the second metal layer 32B made of Al, which has lower tolerability to hydrofluoric acid than the third metal layer 32C, can be protected from hydrofluoric acid contained in the cleaning agent by the third metal layer 32C, and the second metal layer 32B is less likely to be eroded by hydrofluoric acid.

When the non-pixel source electrode 30B and the non-pixel drain electrode 30C are provided after the non-pixel source contact hole CH1 and the non-pixel drain contact hole CH2 are provided in the gate insulating film F3 and the interlayer insulating film F8, as illustrated in FIG. 5, the non-pixel source electrode 30B and the non-pixel drain electrode 30C are connected to the portions of the non-pixel semiconductor portion 30D that are exposed through the non-pixel source contact hole CH1 and the non-pixel drain contact hole CH2, respectively, and are cleaned in advance. Thus, a contact state between the non-pixel semiconductor portion 30D and the non-pixel source electrode 30B and the non-pixel drain electrode 30C, which are the second conductive portions, can be maintained in a favorable manner. When the drive wiring line 33 is provided after the drive wiring line contact hole CH3 is provided in the interlayer insulating film F8, the drive wiring line 33 is connected to the third metal layer 32C of the connection electrode 32 exposed through the drive wiring line contact hole CH3 and the communication hole 32D1. The second metal layer 32B included in the connection electrode 32 is less likely to be over-etched, and the third metal layer 32C included in the connection electrode 32 is less likely to be eroded by hydrofluoric acid, and thus, a contact state between the connection electrode 32 and the drive wiring line 33 can be maintained in a favorable manner. As described above, the contact state between the non-pixel semiconductor portion 30D and the non-pixel source electrode 30B and the non-pixel drain electrode 30C is maintained in a favorable manner, and the contact state between the connection electrode 32 and the drive wiring line 33 is maintained in a favorable manner, and thus the product reliability and the yield of the liquid crystal panel 11 become favorable.

In the present embodiment, the second metal layer 32B of the connection electrode 32 is made of Al, and thus it is suitable for increasing the electrical conductivity of the connection electrode 32. On the other hand, Al constituting the second metal layer 32B has lower tolerability to hydrofluoric acid contained in the cleaning agent than Mo, and is likely to be eluted into hydrofluoric acid. Thus, when the drive wiring line contact hole CH3 is provided in the interlayer insulating film F8 in the manufacturing process of the array substrate 21, if the third metal layer 32C is over-etched and the second metal layer 32B is exposed, thereafter the second metal layer 32B is exposed to the cleaning agent and eluted, and the second metal layer 32B may be damaged. In this regard, when the drive wiring line contact hole CH3 is provided in the interlayer insulating film F8 in the manufacturing process of the array substrate 21, the sacrificial layer 32D is sacrificed, and thus the third metal layer 32C is less likely to be over-etched, and thus a situation in which the second metal layer 32B is exposed to the cleaning agent containing hydrofluoric acid can be avoided. Mo constituting the third metal layer 32C has higher tolerability to hydrofluoric acid contained in the cleaning agent and is less likely to be eluted into hydrofluoric acid than Al, and thus, even when exposed to the cleaning agent through the communication hole 32D1 of the sacrificial layer 32D, a situation in which the third metal layer 32C is eroded is less likely to occur. As described above, the contact state between the connection electrode 32 and the drive wiring line 33 can be maintained in a favorable manner while the conductivity of the connection electrode 32 is increased.

In the present embodiment, the film thickness of the sacrificial layer 32D is equal to 40 nm or less. If the film thickness of the sacrificial layer 32D exceeds 40 nm, when the communication hole 32D1 is provided in the sacrificial layer 32D by the cleaning liquid, the surface area of the communication hole 32D1 becomes too large, and thus, the erosion of the sacrificial layer 32D by the cleaning liquid excessively progresses, and the communication hole 32D1 is likely to be formed over a range wider than the drive wiring line contact hole CH3. In this regard, the surface area of the communication hole 32D1 is sufficiently small by setting the film thickness of the sacrificial layer 32D to be equal to 40 nm or less, and thus the erosion of the sacrificial layer 32D by the cleaning liquid is less likely to be excessively eroded, and a situation in which the communication hole 32D1 becomes wider than the drive wiring line contact hole CH3 is less likely to occur. Thus, a contact state between the drive wiring line 33 and the third metal layer 32C which are connected to each other through the drive wiring line contact hole CH3 and the communication hole 32D1 can be maintained in a favorable manner.

As illustrated in FIG. 5, similar to the above-described connection electrode 32, the non-pixel gate electrode 30A is constituted of a part of the gate constituent film FG and has a four-layer structure. Specifically, the non-pixel gate electrode 30A include, in order from the lower-layer side, a first layer 30A1 constituted of a part of the first metal film F4, a second layer 30A2 constituted of a part of the second metal film F5, a third layer 30A3 constituted of a part of the third metal film F6, and a fourth layer 30A4 constituted of a part of the sacrificial film F7. The fourth layer 30A4 is different from the sacrificial layer 32D in that the fourth layer 32A4 does not include the communication hole 32D1.

The liquid crystal panel 11 according to the present embodiment has the above-described structure, and a manufacturing method thereof will be subsequently described. The manufacturing method of the liquid crystal panel 11 includes a counter substrate manufacturing step of manufacturing the counter substrate 20, an array substrate manufacturing step (semiconductor device manufacturing step) of manufacturing the array substrate 21, and a bonding step of bonding the manufactured counter substrate 20 and the array substrate 21 together. Hereinafter, among the above steps, the array substrate manufacturing step will be described.

The array substrate manufacturing step includes at least a first step of forming the base coat film F1 (base coat film forming step), a second step of forming the semiconductor film F2, performing crystallization with laser, and performing patterning (semiconductor film patterning step), a third step of forming the gate insulating film F3 (gate insulating film forming step), a fourth step of forming the gate constituent film FG and performing patterning (gate constituent film patterning step), a fifth step of selectively reducing the resistance of the structure of the semiconductor film F2 (reduced resistance step, annealing step), a sixth step of forming the interlayer insulating film F8 and patterning the gate insulating film F3 and the interlayer insulating film F8 (insulating film patterning step), a seventh step of cleaning the structure of the semiconductor film F2 with the cleaning liquid (cleaning step), and an eighth step of forming the fourth metal film F9 and performing patterning (second metal film patterning step).

The term “patterning” described above means a process of a film based on a general photolithography method. Specifically, the process, that is, the patterning of a film to be processed is performed by performing the film formation of a photoresist film on the film to be processed, exposing the photoresist film with an exposure device through a photomask having a predetermined opening pattern, and then developing the photoresist film, and performing etching through the developed photoresist film.

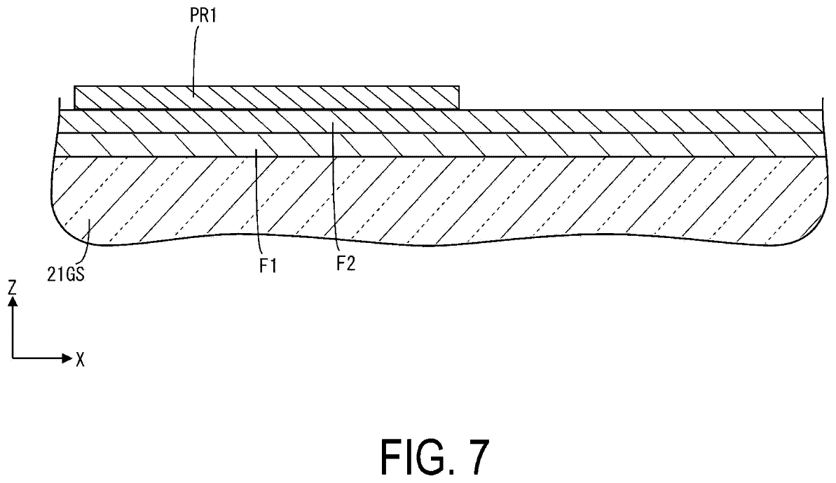

In the first step, as illustrated in FIG. 6, the base coat film F1 is formed on the glass substrate 21GS of the array substrate 21. In the next second step, the semiconductor film F2 is formed on the upper-layer side of the base coat film F1. By performing a laser crystallization process on the formed semiconductor film F2, the semiconductor film F2 is made polycrystalline. Subsequently, a first photoresist film is formed on the upper-layer side of the semiconductor film F2, and the first photoresist film is exposed to light by using an exposure device and a first photomask including a predetermined opening pattern (both the exposure device and the first photomask are not illustrated), and then developed. Then, as illustrated in FIG. 7, a first photoresist pattern PR1 having a shape obtained by transferring the opening pattern of the first photomask remains on the semiconductor film F2. The remaining first photoresist pattern PR1 is used as a mask to etch the semiconductor film F2 (dry etching or wet etching). Then, in the non-display region NAA, the non-pixel semiconductor portion 30D located in a range overlapping the first photoresist pattern PR1 is provided (see FIG. 8). Note that in the display region AA, the pixel semiconductor portion 24D is provided (see FIG. 3). After the etching of the semiconductor film F2 is finished, the first photoresist pattern PR1 is removed by a peeling liquid.

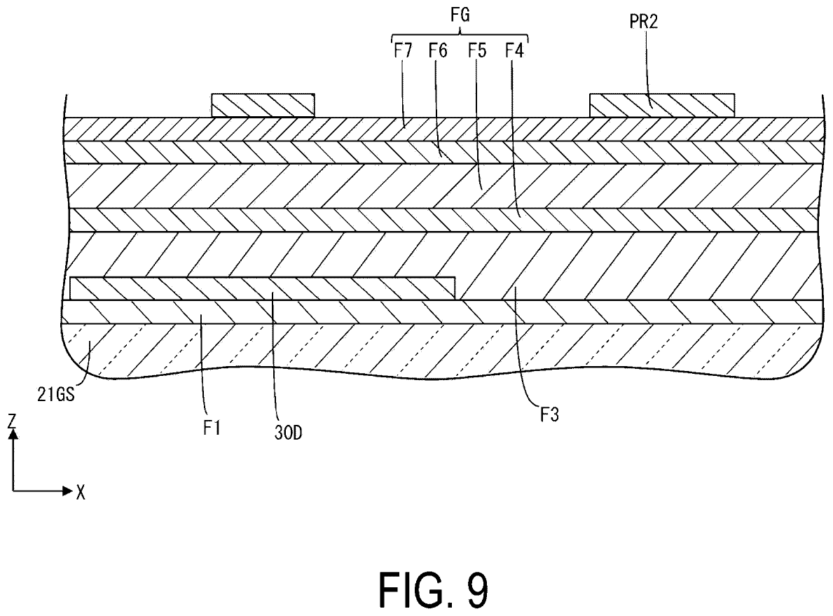

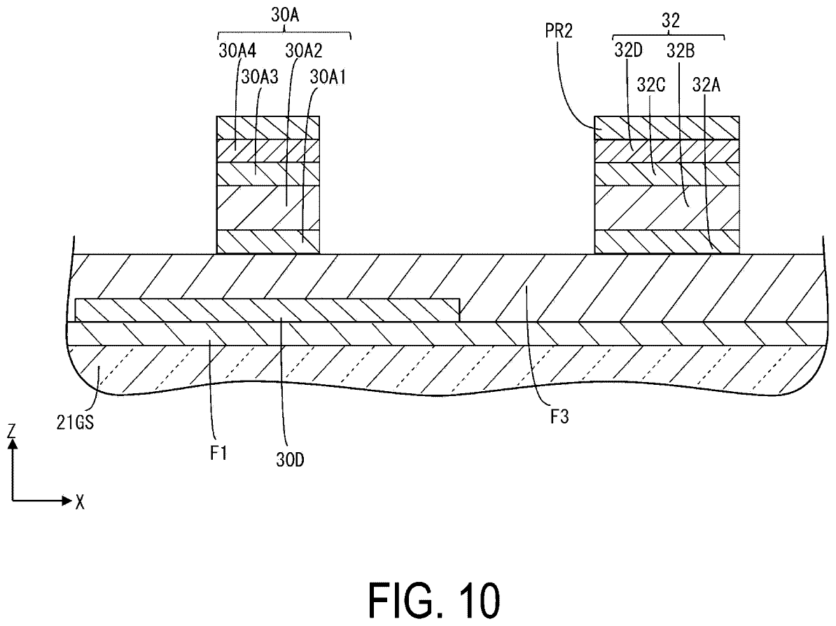

In the third step, as illustrated in FIG. 8, the gate insulating film F3 is formed on the upper-layer side of the semiconductor film F2. In the next fourth step, the gate constituent film FG is formed on the upper-layer side of the gate insulating film F3. Specifically, the first metal film F4, the second metal film F5, the third metal film F6, and the sacrificial film F7 are formed in this order on the upper-layer side of the gate insulating film F3. Subsequently, a second photoresist film is formed on the upper-layer side of the sacrificial film F7, and a second photoresist film is exposed to light by using an exposure device and a second photomask including a predetermined opening pattern (both the exposure device and the second photomask are not illustrated), and then developed. Then, as illustrated in FIG. 9, a second photoresist pattern PR2 having a shape obtained by transferring the opening pattern of the second photomask remains on the sacrificial film F7. The gate constituent film FG is wet-etched using the remaining second photoresist pattern PR2 as a mask. Then, in the non-display region NAA, as illustrated in FIG. 10, the non-pixel gate electrode 30A, the connection wiring line 31 (see FIG. 4), and the connection electrode 32 each located in a range overlapping the second photoresist pattern PR2 are provided. The connection electrode 32 among them includes, in order from the lower-layer side, the first metal layer 32A constituted of a part of the first metal film F4, the second metal layer 32B constituted of a part of the second metal film F5, the third metal layer 32C constituted of a part of the third metal film F6, and the sacrificial layer 32D constituted of a part of the sacrificial film F7. Note that in the display region AA, the pixel gate electrode 24A is provided (see FIG. 3). After the wet etching of the gate constituent film FG is finished, the second photoresist pattern PR2 is removed by a peeling liquid.

In the fifth step, by using a structure constituted of the gate constituent film FG as a mask to the structure constituted of the semiconductor film F2, a reduced resistance process is selectively performed. The reduced resistance process includes a doping process using, for example, an ion species such as B or P, an annealing process, and the like. Specifically, in the non-display region NAA, a portion of the non-pixel semiconductor portion 30D not overlapping the non-pixel gate electrode 30A is selectively reduced in the resistance. In the display region AA, a portion of the pixel semiconductor portion 24D not overlapping the pixel gate electrode 24A is selectively reduced in the resistance (see FIG. 3). At this time, when the semiconductor material is used as the material of the sacrificial film F7, both of the sacrificial layer 32D included in the connection electrode 32 and the fourth layer 30A4 included in the non-pixel gate electrode 30A are reduced in the resistance over the entire regions.

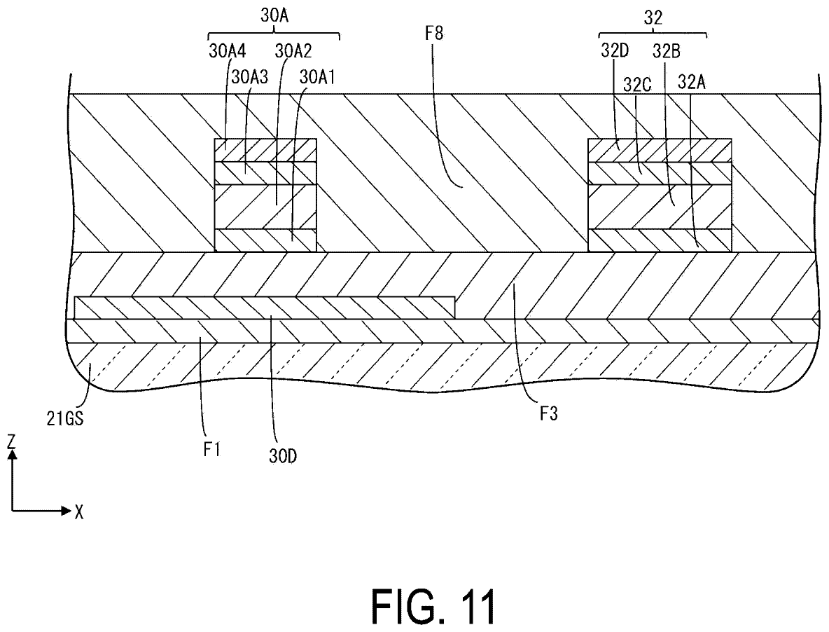

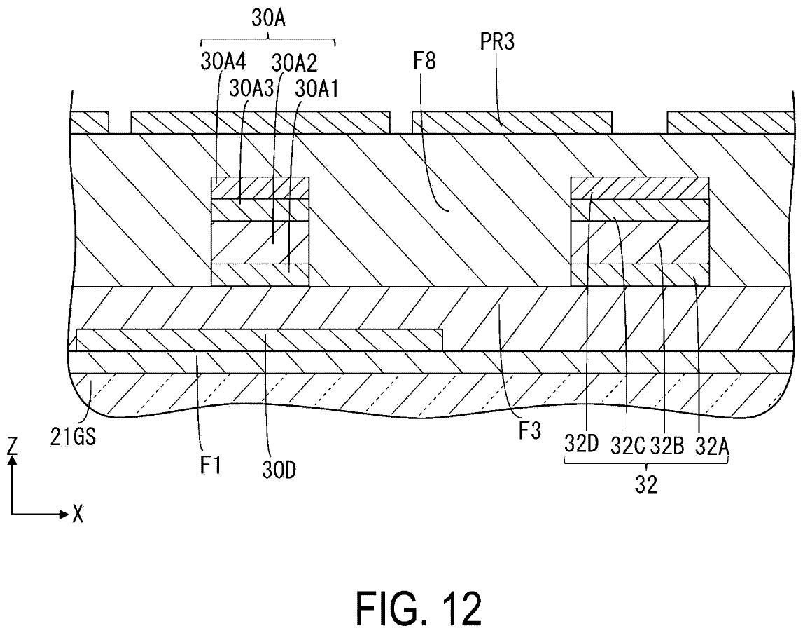

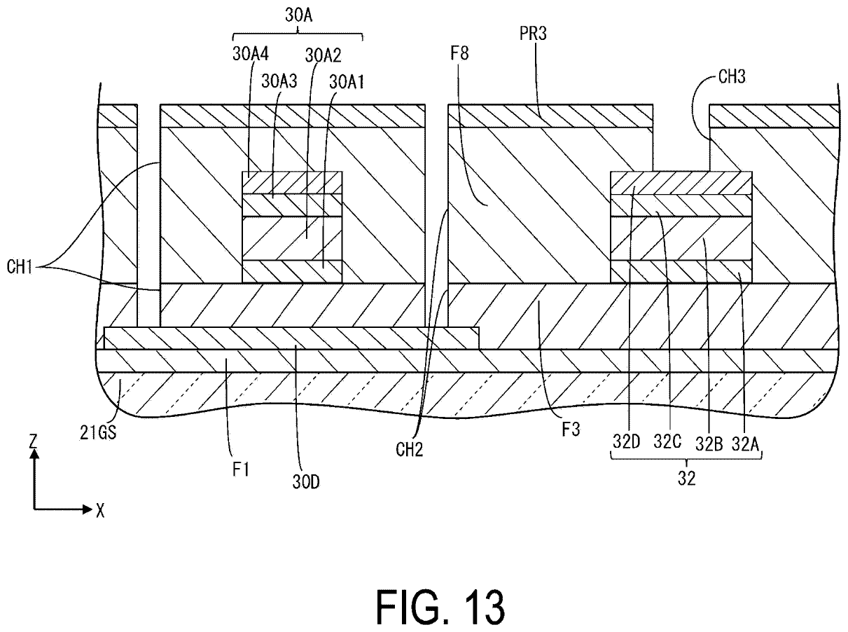

In the sixth step, as illustrated in FIG. 11, the interlayer insulating film F8 is formed on the upper-layer side of the gate constituent film FG. Subsequently, a third photoresist film is formed on the upper-layer side of the interlayer insulating film F8, and the third photoresist film is exposed to light by using an exposure device and a third photomask including a predetermined opening pattern (both of the exposure device and the third photomask are not illustrated), and then developed. Then, as illustrated in FIG. 12, a third photoresist pattern PR3 having a shape obtained by transferring the opening pattern of the third photomask remains on the interlayer insulating film F8. The interlayer insulating film F8 is dry-etched using the remaining third photoresist pattern PR3 as a mask. Then, in the non-display region NAA, as illustrated in FIG. 13, a part of the non-pixel source contact hole CH1, a part of the non-pixel drain contact hole CH2, and the drive wiring line contact hole CH3 are provided in a range of the interlayer insulating film F8 overlapping the opening portion of the third photoresist pattern PR3. When the dry etching is further continued, in the non-display region NAA, a remaining portion of the non-pixel source contact hole CH1 and a remaining portion of the non-pixel drain contact hole CH2 are provided in a range of the gate insulating film F3 overlapping the opening portion of the third photoresist pattern PR3. While the gate insulating film F3 is dry-etched, the connection electrode 32 exposed through the drive wiring line contact hole CH3 of the interlayer insulating film F8 are also dry-etched. In contrast, the sacrificial layer 32D having excellent tolerability to dry etching is provided as the uppermost layer of the connection electrode 32, and thus even when the sacrificial layer 32D is slightly reduced in film thickness by dry etching, a situation in which the sacrificial layer 32D is burned off is less likely to occur. In particular, in the present embodiment, the film thickness of the sacrificial layer 32D is equal to 10 nm or more, and thus the situation in which the sacrificial layer 32D is burned off by dry etching is further less likely to occur. As described above, by sacrificing the sacrificial layer 32D, a situation in which the third metal layer 32C and the second metal layer 32B having low tolerability to dry etching are over-etched is less likely to occur. Note that in the display region AA, at least the pixel source contact hole and the pixel drain contact hole are provided. After the dry etching of the interlayer insulating film F8 and the gate insulating film F3 is finished, the third photoresist pattern PR3 is removed by a peeling liquid.

In the seventh step, the cleaning agent containing hydrofluoric acid is supplied onto the interlayer insulating film F8 by a cleaning apparatus. Then, the cleaning agent enters the inside of each of the non-pixel source contact hole CH1, the non-pixel drain contact hole CH2, and the drive wiring line contact hole CH3. Inside the non-pixel source contact hole CH1 and the non-pixel drain contact hole CH2, portions of the non-pixel semiconductor portion 30D facing the non-pixel source contact hole CH1 and the non-pixel drain contact hole CH2 are cleaned with the cleaning agent, and the surface states thereof are improved. Inside the drive wiring line contact hole CH3, a portion of the sacrificial layer 32D of the connection electrode 32 facing the drive wiring line contact hole CH3 is eluted by being exposed to hydrofluoric acid contained in the cleaning agent. As a result, the communication hole 32D1 communicating with the drive wiring line contact hole CH3 is provided in the sacrificial layer 32D. At this time, the third metal layer 32C made of Mo having high tolerability to hydrofluoric acid remains on the lower-layer side of the sacrificial layer 32D without being over-etched in the sixth step, and thus even when the third metal layer 32C is exposed to hydrofluoric acid through the communication hole 32D1, a situation in which the third metal layer 32C is eroded is less likely to occur. Thus, the second metal layer 32B located on the lower-layer side of the third metal layer 32C and made of Al having low tolerability to hydrofluoric acid can be protected from hydrofluoric acid contained in the cleaning agent. Thus, a situation in which the second metal layer 32B is exposed to hydrofluoric acid can be avoided, and a situation in which the second metal layer 32B is eroded by hydrofluoric acid can be made less likely to occur.

In particular, in the present embodiment, the film thickness of the sacrificial film F7 is equal to 40 nm or less. If the film thickness of the sacrificial layer 32D exceeds 40 nm, when the communication hole 32D1 is provided in the sacrificial layer 32D by hydrofluoric acid contained in the cleaning liquid, the surface area of the communication hole 32D1 becomes too large, and thus, the erosion of the sacrificial layer 32D by hydrofluoric acid contained in the cleaning liquid excessively progresses, and the communication hole 32D1 is likely to be formed over a range wider than the drive wiring line contact hole CH3. In this regard, the surface area of the communication hole 32D1 is sufficiently small by setting the film thickness of the sacrificial layer 32D to be equal to 40 nm or less, and thus the erosion of the sacrificial layer 32D by hydrofluoric acid contained in the cleaning liquid is less likely to be excessively eroded, and a situation in which the communication hole 32D1 becomes wider than the drive wiring line contact hole CH3 is less likely to occur.

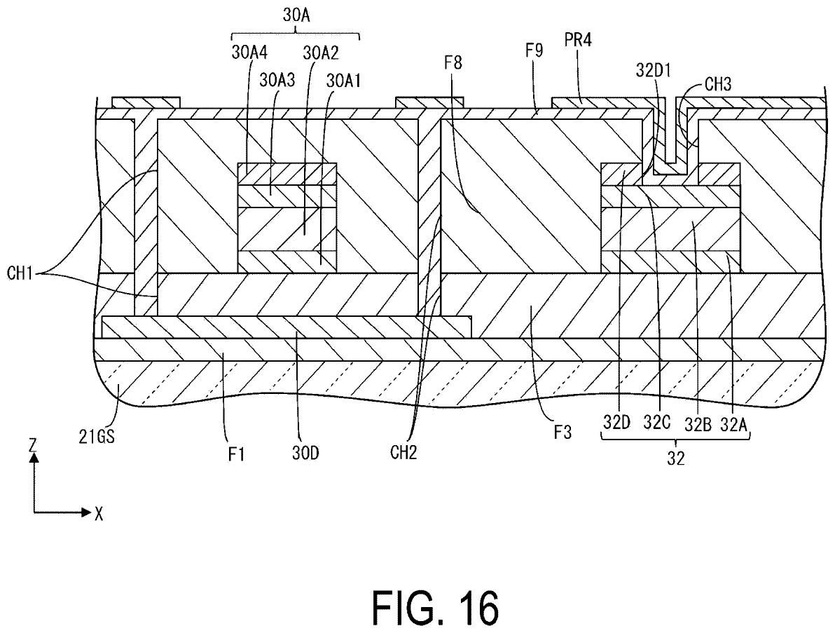

In the eighth step, as illustrated in FIG. 15, the fourth metal film F9 is formed on the interlayer insulating film F8. Subsequently, a fourth photoresist film is formed on the upper-layer side of the fourth metal film F9, and a fourth photoresist film is exposed to light by using an exposure device and a fourth photomask including a predetermined opening pattern (both of the exposure device and the fourth photomask are not illustrated), and then developed. Then, as illustrated in FIG. 16, a fourth photoresist pattern PR4 having a shape obtained by transferring the opening pattern of the fourth photomask remains on the fourth metal film F9. The remaining fourth photoresist pattern PR4 is used as a mask to etch the fourth metal film F9 (dry etching or wet etching). Then, in the non-display region NAA, the non-pixel source electrode 30B, the non-pixel drain electrode 30C, and the drive wiring line 33 located in a range overlapping the fourth photoresist pattern PR4 are provided (see FIG. 5). In the display region AA, the pixel source electrode 24B and the pixel drain electrode 24C are provided (see FIG. 3). After the etching of the fourth metal film F9 is finished, the fourth photoresist pattern PR4 is removed by a peeling liquid.

The non-pixel source electrode 30B and the non-pixel drain electrode 30C provided in the eighth step are connected to the non-pixel semiconductor portion 30D through the non-pixel source contact hole CH1 and the non-pixel drain contact hole CH2, respectively, of the interlayer insulating film F8. The surface states of the portions of the non-pixel semiconductor portion 30D in contact with the non-pixel source electrode 30B and the non-pixel drain electrode 30C have been improved by being cleaned with the cleaning liquid in advance in the seventh step, and thus the contact state between the portions and the non-pixel source electrode 30B and the non-pixel drain electrode 30C becomes favorable. The drive wiring line 33 provided in the eighth step is connected to the third metal layer 32C of the connection electrode 32 through the drive wiring line contact hole CH3 of the interlayer insulating film F8 and the communication hole 32D1 of the sacrificial layer 32D of the connection electrode 32. The third metal layer 32C, which is in direct contact with the drive wiring line 33, in the connection electrode 32 is protected by the sacrificial layer 32D in the sixth step, and thus is less likely to be over-etched, and is less likely to be eroded by hydrofluoric acid contained in the cleaning agent in the seventh step, and thus the state of being in contact with the drive wiring line 33 becomes favorable. The second metal layer 32B located on the lower-layer side of the third metal layer 32C in the connection electrode 32 is protected by the sacrificial layer 32D in the sixth step, and thus is less likely to be over-etched, and is prevented from being directly exposed to hydrofluoric acid contained in the cleaning agent in the seventh step, and thus a situation in which the second metal layer 32B is eroded by hydrofluoric acid is less likely to occur. As described above, the contact state between the connection electrode 32 and the drive wiring line 33 can be maintained in a favorable manner.

In addition, the erosion of the sacrificial layer 32D by hydrofluoric acid contained in the cleaning liquid is less likely to excessively progress in the seventh step by setting the film thickness of the sacrificial film F7 to be equal to 40 nm or less, and a situation in which the communication hole 32D1 becomes wider than the drive wiring line contact hole CH3 is less likely to occur. Thus, a contact state between the drive wiring line 33 and the third metal layer 32C which are connected to each other through the drive wiring line contact hole CH3 and the communication hole 32D1 can be maintained in a favorable manner.

Furthermore, in the present embodiment, the sacrificial layer 32D included in the connection electrode 32 is made conductive by performing the reduced resistance process in the fifth step, even when the communication hole 32D1 is provided not to penetrate the sacrificial layer 32D when cleaning with the cleaning agent is performed in the seventh step, the drive wiring line 33 can be electrically connected to the third metal layer 32C via the sacrificial layer 32D that is made conductive. Thus, the connection reliability between the connection electrode 32 and the drive wiring line 33 can be increased.

As described above, the array substrate (semiconductor device) 21 according to the present embodiment includes the non-pixel semiconductor portion (semiconductor portion) 30D constituted of a part of the semiconductor film F2, the gate insulating film (first insulating film) F3 disposed on an upper-layer side of the semiconductor film F2, the connection electrode (first conductive portion) 32 disposed on an upper-layer side of the gate insulating film F3 and disposed not to overlap the non-pixel semiconductor portion 30D, the interlayer insulating film (second insulating film) F8 disposed on an upper-layer side of the gate insulating film F3 and the connection electrode 32, the non-pixel source electrode 30B and the non-pixel drain electrode 30C, which are the second conductive portions, disposed on an upper-layer side of the interlayer insulating film F8 and disposed to overlap the non-pixel semiconductor portion 30D, and the drive wiring line (third conductive portion) 33 disposed on an upper-layer side of the interlayer insulating film F8 and disposed to overlap the connection electrode 32, in which the gate insulating film F3 and the interlayer insulating film F8 are provided with the non-pixel source contact hole CH1 and the non-pixel drain contact hole CH2, which are the first contact holes, disposed to overlap both the non-pixel semiconductor portion 30D and the non-pixel source electrode 30B and the non-pixel drain electrode 30C, which are the second conductive portions, the interlayer insulating film F8 is provided with the drive wiring line contact hole (second contact hole) CH3 disposed to overlap both the connection electrode 32 and the drive wiring line 33, the connection electrode 32 includes at least the second metal layer (first conductive layer) 32B constituted of a part of the second metal film (first conductive film) F5 disposed on the upper-layer side of the gate insulating film F3, the third metal layer (second conductive layer) 32C constituted of a part of the third metal film (second conductive film) F6 disposed on the upper-layer side of the second metal film F5, and the sacrificial layer 32D constituted of a part of the sacrificial film F7 disposed on an upper-layer side of the third metal film F6, and the sacrificial layer 32D is made of a semiconductor material or a conductive material, and includes a communication hole 32D1 communicating with the drive wiring line contact hole CH3.

The non-pixel source electrode 30B and the non-pixel drain electrode 30C, which are the second conductive portions, are connected to the non-pixel semiconductor portion 30D through the non-pixel source contact hole CH1 and the non-pixel drain contact hole CH2, respectively, which are the first contact holes provided in the gate insulating film F3 and the interlayer insulating film F8. The drive wiring line 33 is connected to the connection electrode 32 through the drive wiring line contact hole CH3 provided in the interlayer insulating film F8. Here, the connection electrode 32 includes, in order from the lower-layer side, at least the second metal layer 32B, the third metal layer 32C, and the sacrificial layer 32D, and the sacrificial layer 32D is made of a semiconductor material or a conductive material. Thus, in the manufacturing process, when the non-pixel source contact hole CH1 and the non-pixel drain contact hole CH2, which are the first contact holes, are provided by etching the gate insulating film F3 and the interlayer insulating film F8, and the drive wiring line contact hole CH3 is provided by etching the interlayer insulating film F8, the sacrificial layer 32D located as the uppermost layer of the connection electrode 32 is sacrificed, and a situation in which the second metal layer 32B and the third metal layer 32C are over-etched is less likely to occur.

In the manufacturing process, when a cleaning agent containing, for example, hydrofluoric acid is supplied to the non-pixel source contact hole CH1 and the non-pixel drain contact hole CH2, which are the first contact holes provided in the gate insulating film F3 and the interlayer insulating film F8, the surface of the non-pixel semiconductor portion 30D exposed through the non-pixel source contact hole CH1 and the non-pixel drain contact hole CH2, which are the first contact holes, can be cleaned. At this time, when the cleaning agent is supplied to the drive wiring line contact hole CH3 provided in the interlayer insulating film F8, the sacrificial layer 32D exposed through the drive wiring line contact hole CH3 is eluted into the cleaning agent, and thus the sacrificial layer 32D is provided with the communication hole 32D1 communicating with the drive wiring line contact hole CH3. The third metal layer 32C remains on the lower-layer side of the sacrificial layer 32D, and thus the second metal layer 32B can be protected from hydrofluoric acid contained in the cleaning agent, and the second metal layer 32B is less likely to be eroded by hydrofluoric acid. When the non-pixel source electrode 30B and the non-pixel drain electrode 30C, which are the second conductive portions, are provided after the non-pixel source contact hole CH1 and the non-pixel drain contact hole CH2, which are the first contact holes, are provided in the gate insulating film F3 and the interlayer insulating film F8, the non-pixel source electrode 30B and the non-pixel drain electrode 30C, which are the second conductive portions, are connected to the portions of the non-pixel semiconductor portion 30D that are exposed through the non-pixel source contact hole CH1 and the non-pixel drain contact hole CH2, respectively, which are the first contact holes, and are cleaned in advance. Thus, a contact state between the non-pixel semiconductor portion 30D and the non-pixel source electrode 30B and the non-pixel drain electrode 30C, which are the second conductive portions, is maintained in a favorable manner. When the drive wiring line 33 is provided after the drive wiring line contact hole CH3 is provided in the interlayer insulating film F8, the drive wiring line 33 is connected to the third metal layer 32C of the connection electrode 32 exposed through the drive wiring line contact hole CH3 and the communication hole 32D1. The second metal layer 32B included in the connection electrode 32 is less likely to be over-etched, and the third metal layer 32C included in the connection electrode 32 is less likely to be eroded by hydrofluoric acid, and thus, a contact state between the connection electrode 32 and the drive wiring line 33 can be maintained in a favorable manner.

The sacrificial layer 32D is made of an oxide semiconductor material that is the semiconductor material. When the drive wiring line contact hole CH3 is provided by etching the interlayer insulating film F8 in the manufacturing process, the sacrificial layer 32D made of the oxide semiconductor material is less likely to be etched, and thus a situation in which the second metal layer 32B and the third metal layer 32C are over-etched is less likely to occur. On the other hand, when the cleaning agent containing hydrofluoric acid is supplied to the drive wiring line contact hole CH3 provided in the interlayer insulating film F8, the sacrificial layer 32D made of the oxide semiconductor material is likely to be eluted into hydrofluoric acid, and thus, the communication hole 32D1 communicating with the drive wiring line contact hole CH3 is likely to be provided in the sacrificial layer 32D. This increases the certainty that the third metal layer 32C is exposed through the communication hole 32D1 of the sacrificial layer 32D.

The sacrificial layer 32D is made of a transparent electrode material that is the conductive material. When the drive wiring line contact hole CH3 is provided by etching the interlayer insulating film F8 in the manufacturing process, the sacrificial layer 32D made of the transparent electrode material is less likely to be etched, and thus a situation in which the second metal layer 32B and the third metal layer 32C are over-etched is less likely to occur. On the other hand, when the cleaning agent containing hydrofluoric acid is supplied to the drive wiring line contact hole CH3 provided in the interlayer insulating film F8, the sacrificial layer 32D made of the transparent electrode material is likely to be eluted into hydrofluoric acid, and thus, the communication hole 32D1 communicating with the drive wiring line contact hole CH3 is likely to be provided in the sacrificial layer 32D. This increases the certainty that the third metal layer 32C is exposed through the communication hole 32D1 of the sacrificial layer 32D.

The second metal layer 32B contains aluminum, and the third metal layer 32C contains molybdenum. Aluminum has a lower sheet resistance than tantalum and tungsten. Thus, when the second metal layer 32B of the connection electrode 32 is made of aluminum, it is suitable for increasing the electrical conductivity of the connection electrode 32. On the other hand, aluminum has lower tolerability to hydrofluoric acid contained in the cleaning agent than molybdenum, and is likely to be eluted into hydrofluoric acid. Thus, when the drive wiring line contact hole CH3 is provided in the interlayer insulating film F8 in the manufacturing process, if the third metal layer 32C is over-etched and the second metal layer 32B is exposed, thereafter the second metal layer 32B is exposed to the cleaning agent and eluted, and the second metal layer 32B may be damaged. In this regard, when the drive wiring line contact hole CH3 is provided in the interlayer insulating film F8 in the manufacturing process, the sacrificial layer 32D is sacrificed, and thus the third metal layer 32C is less likely to be over-etched, and thus a situation in which the second metal layer 32B is exposed to the cleaning agent containing hydrofluoric acid can be avoided. Molybdenum constituting the third metal layer 32C has higher tolerability to hydrofluoric acid contained in the cleaning agent and is less likely to be eluted into hydrofluoric acid than aluminum, and thus, even when exposed to the cleaning agent through the communication hole 32D1 of the sacrificial layer 32D, a situation in which the third metal layer 32C is eroded is less likely to occur. As described above, the contact state between the connection electrode 32 and the drive wiring line 33 can be maintained in a favorable manner while the conductivity of the connection electrode 32 is increased.

The film thickness of the sacrificial layer 32D is equal to 40 nm or less. If the film thickness of the sacrificial layer 32D exceeds 40 nm, when the communication hole 32D1 is provided in the sacrificial layer 32D by the cleaning liquid, the surface area of the communication hole 32D1 becomes too large, and thus, the erosion of the sacrificial layer 32D by the cleaning liquid excessively progresses, and the communication hole 32D1 is likely to be formed over a range wider than the drive wiring line contact hole CH3. In this regard, the surface area of the communication hole 32D1 is sufficiently small by setting the film thickness of the sacrificial layer 32D to be equal to 40 nm or less, and thus the erosion of the sacrificial layer 32D by the cleaning liquid is less likely to excessively progress, and a situation in which the communication hole 32D1 becomes wider than the drive wiring line contact hole CH3 is less likely to occur. Thus, a contact state between the drive wiring line 33 and the third metal layer 32C which are connected to each other through the drive wiring line contact hole CH3 and the communication hole 32D1 can be maintained in a favorable manner.

The liquid crystal panel (display device) 11 according to the present embodiment includes the array substrate 21 described above and the counter substrate 20 disposed to face the array substrate 21. According to such a liquid crystal panel 11, a contact state between the non-pixel semiconductor portion 30D and the non-pixel source electrode 30B and the non-pixel drain electrode 30C, which are the second conductive portions, is maintained in a favorable manner, and a contact state between the connection electrode 32 and the drive wiring line 33 is maintained in a favorable manner, and thus the product reliability and the yield become favorable.

A manufacturing method of the array substrate 21 according to the present embodiment includes forming the semiconductor film F2, and patterning the formed semiconductor film F2 to provide the non-pixel semiconductor portion 30D, forming the gate insulating film F3 on an upper-layer side of the semiconductor film F2, forming the connection electrode 32 including, in order from a lower-layer side, at least the second metal layer 32B constituted of a part of the second metal film F5, the third metal layer 32C constituted of a part of the third metal film F6, and the sacrificial layer 32D constituted of a part of the sacrificial film F7 at a position not overlapping the non-pixel semiconductor portion 30D by sequentially forming at least the second metal film F5, the third metal film F6, and the sacrificial film F7 made of a semiconductor material or a conductive material each on an upper-layer side of the gate insulating film F3 and patterning the second metal film F5, the third metal film F6, and the sacrificial film F7, forming the interlayer insulating film F8 on an upper-layer side of the gate insulating film F3 and the connection electrode 32, providing a part of the non-pixel source contact hole CH1 and a part of the non-pixel drain contact hole CH2, which are the first contact holes, at a position overlapping the non-pixel semiconductor portion 30D and the drive wiring line contact hole CH3 at a position overlapping the connection electrode 32 by patterning the interlayer insulating film F8, providing remaining portions of the non-pixel source contact hole CH1 and the non-pixel drain contact hole CH2, which are the first contact holes, by patterning the gate insulating film F3 following the interlayer insulating film F8, cleaning the portions of the non-pixel semiconductor portion 30D facing the non-pixel source contact hole CH1 and the non-pixel drain contact hole CH2, which are the first contact holes, and providing the communication hole 32D1 communicating with the drive wiring line contact hole CH3 in the sacrificial layer 32D of the connection electrode 32, by supplying the cleaning agent containing hydrofluoric acid to the inside of the non-pixel source contact hole CH1 and the non-pixel drain contact hole CH2, which are the first contact holes, and the drive wiring line contact hole CH3, providing the non-pixel source electrode 30B and the non-pixel drain electrode 30C, which are the second conductive portions, on an upper-layer side of the interlayer insulating film F8 at a position overlapping the non-pixel semiconductor portion 30D, and connecting the non-pixel source electrode 30B and the non-pixel drain electrode 30C, which are the second conductive portions, to the non-pixel semiconductor portion 30D through non-pixel source contact hole CH1 and the non-pixel drain contact hole CH2, which are the first contact holes, and providing the drive wiring line 33 on an upper-layer side of the interlayer insulating film F8 at a position overlapping the connection electrode 32, and connecting the drive wiring line 33 to the third metal layer 32C of the connection electrode 32 through the drive wiring line contact hole CH3 and the communication hole 32D1.

When a part of the non-pixel source contact hole CH1 and a part of the non-pixel drain contact hole CH2, which are the first contact holes, and the drain wiring line contact hole CH3 are provided by etching the interlayer insulating film F8, and the remaining parts of the non-pixel source contact hole CH1 and the non-pixel drain contact hole CH2, which are the first contact holes, are provided by etching the gate insulating film F3, the sacrificial layer 32D located as the uppermost layer of the connection electrode 32 is sacrificed, and thus a situation in which the second metal layer 32B and the third metal layer 32C are over-etched is less likely to occur. When the cleaning agent containing hydrofluoric acid is supplied to the non-pixel source contact hole CH1 and the non-pixel drain contact hole CH2, which are the first contact holes of the gate insulating film F3 and the interlayer insulating film F8, and the drive wiring line contact hole CH3 of the interlayer insulating film F8, the surface of the non-pixel semiconductor portion 30D exposed through the non-pixel source contact hole CH1 and the non-pixel drain contact hole CH2, which are the first contact holes, is cleaned, the sacrificial layer 32D exposed through the drive wiring line contact hole CH3 is eluted into the cleaning agent, and the sacrificial layer 32D is provided with the communication hole 32D1 communicating with the drive wiring line contact hole CH3. At this time, the third metal layer 32C remains on the lower-layer side of the sacrificial layer 32D, and thus the second metal layer 32B can be protected from hydrofluoric acid contained in the cleaning agent, and the second metal layer 32B is less likely to be eroded by hydrofluoric acid. When the non-pixel source electrode 30B and the non-pixel drain electrode 30C, which are the second conductive portions, are provided, the non-pixel source electrode 30B and the non-pixel drain electrode 30C, which are the second conductive portions, are connected to the portions of the non-pixel semiconductor portion 30D that are exposed through the non-pixel source contact hole CH1 and the non-pixel drain contact hole CH2, respectively, which are the first contact holes, and are cleaned in advance. Thus, a contact state between the non-pixel semiconductor portion 30D and the non-pixel source electrode 30B and the non-pixel drain electrode 30C, which are the second conductive portions, is maintained in a favorable manner. When the drive wiring line 33 is provided, the drive wiring line 33 is connected to the third metal layer 32C of the connection electrode 32 exposed through the drive wiring line contact hole CH3 and the communication hole 32D1. The second metal layer 32B included in the connection electrode 32 is less likely to be over-etched, and the third metal layer 32C included in the connection electrode 32 is less likely to be eroded by hydrofluoric acid, and thus, a contact state between the connection electrode 32 and the drive wiring line 33 can be maintained in a favorable manner.

In addition, the sacrificial film F7 made of the oxide semiconductor material that is the semiconductor material is formed, and the connection electrode 32 is provided, and then annealing is performed. The sacrificial layer 32D included in the connection electrode 32 is made of the oxide semiconductor material, and is made conductive as the annealing process is performed. Thus, even when the communication hole 32D1 is provided not to penetrate the sacrificial layer 32D when cleaning with the cleaning agent is performed, the drive wiring line 33 can be electrically connected to the third metal layer 32C via the sacrificial layer 32D that is made conductive. Thus, the connection reliability between the connection electrode 32 and the drive wiring line 33 can be increased.

### Other Embodiments

The techniques disclosed herein are not limited to the embodiments described above and illustrated in the drawings, and the following embodiments, for example, are also included within the technical scope.

(1) The sacrificial film F7 may be a layered film of the semiconductor material and the transparent electrode material. The sacrificial film F7 may be a layered film of a plurality of the semiconductor materials or a layered film of a plurality of the transparent electrode materials.

(2) A specific material used in the sacrificial film F7 can be changed as appropriate other than the above. Specifically, as the material of the sacrificial film F7, the oxide semiconductor material such as an In—W—Zn—O-based semiconductor material, an In—W—Sn—Zn—O-based semiconductor material, an In—Al—Zn—O-based semiconductor material, an In—Al—Sn—Zn—O-based semiconductor material, a Zn—O-based semiconductor material, a Zn—Ti—O-based semiconductor material, a Cd—Ge—O-based semiconductor material, a Cd—Pb—O-based semiconductor material, CdO (cadmium oxide), a Mg—Zn—O-based semiconductor material, an In—Ga—Sn—O-based semiconductor material, a Zr—In—Zn—O-based semiconductor material, a Hf—In—Zn—O-based semiconductor material, an Al—Ga—Zn—O-based semiconductor material, a Ga—Zn—O-based semiconductor material, an In—Ga—Zn—Sn—O-based semiconductor material, or the like can be used. The material of the sacrificial film F7 may be an amorphous silicon material other than the oxide semiconductor material. The sacrificial layer 32D may be a metal material other than the semiconductor material.

(3) The specific numerical value of the film thickness of the sacrificial film F7 may be changed as appropriate in a range other than the above.

(4) The specific materials of the first metal film F4 and the third metal film F6 may be changed as appropriate other than the above, and may be, for example, titanium (Ti). The first metal film F4 and the third metal film F6 are not limited to be made of a single material, and may be, for example, alloys using a plurality of materials.

(5) The specific material of the second metal film F5 may be changed as appropriate other than the above, and may be, for example, copper (Cu) or gold (Au).

(6) The specific numerical values of the film thicknesses of the first metal film F4, the second metal film F5, and the third metal film F6 may be changed as appropriate other than the above.

(7) The connection electrode 32 may have a three-layer structure of the second metal layer 32B, the third metal layer 32C, and the sacrificial layer 32D, with the first metal layer 32A omitted. The connection electrode 32 may have a layered structure of five or more layers, and in this case, an additional metal layer may be disposed on the lower-layer side of the first metal layer 32A, or may be interposed between the first metal layer 32A and the second metal layer 32B.

(8) The specific planar shapes (planar patterns) of the non-pixel gate electrode 30A, the non-pixel source electrode 30B, the non-pixel drain electrode 30C, the non-pixel semiconductor portion 30D, the connection wiring line 31, the connection electrode 32, and the drive wiring line 33 may be changed as appropriate other than those illustrated in the drawings. For example, the non-pixel gate electrode 30A, the non-pixel source electrode 30B, the non-pixel drain electrode 30C, and the connection electrode 32 may have a horizontally elongated shape in a plan view. The non-pixel semiconductor portion 30D, the connection wiring line 31, and the drive wiring line 33 may have a planar shape extending along the Y-axis direction or extending along an oblique direction inclined with respect to both the X-axis direction and the Y-axis direction.

(9) In the manufacturing method of the array substrate 21, the fifth step (reduced resistance step, annealing step) may be performed after the sixth step.

(10) The gate wiring line 26 extends to the outside of the display region AA (non-display region NAA) and is connected to the gate circuit portion 14, but an extending portion of the gate wiring line 26 disposed in the non-display region NAA may be constituted of a part of the fourth metal film F9. In this case, a main body portion of the gate wiring line 26, the main body portion being constituted of a part of the gate constituent film FG, and the extending portion constituted of a part of the fourth metal film F9, are partially overlapped each other, and a contact hole is provided in the interlayer insulating film F8 interposed between the overlapped portions, so that the main body portion and the extending portion can be connected to each other. In such a configuration, the overlapping portion of the main body portion with the extending portion is the “first conductive portion”, the overlapping portion of the extending portion with the main body portion is a “third conductive portion”, the contact hole connecting the main body portion and the extending portion is the “second contact hole”, the pixel source electrode 24B and the pixel drain electrode 24C provided in the pixel TFT 24 are the “second conductive portions”, the pixel semiconductor portion 24D is the “semiconductor portion”, and the pixel source contact hole and the pixel drain contact hole are the “first contact holes”.

(11) In a case where a switch circuit (source shared driving (SSD) circuit) that distributes an image signal supplied from the driver 12 to the plurality of source wiring lines 27 are provided in the array substrate 21, respectively, the non-pixel TFT 30 may be included in the switch circuit. Other than the above the non-pixel TFT 30 may be provided so as to be provided in the array substrate 21 and included in a circuit other than the gate circuit portion 14 and the switch circuit.

(12) The pixel TFT 24 and the non-pixel TFT 30 may be a double gate type or the like other than the top gate type. In this case, for example, a metal film may be formed on the lower-layer side of the base coat film F1, and a pixel bottom gate electrode overlapping the pixel semiconductor portion 24D and a non-pixel bottom gate electrode overlapping the non-pixel semiconductor portion 30D may be provided using the metal film.

(13) The driver 12 may be mounted by chip on film (COF) on the flexible substrate 13, which is mounted on the array substrate 21 by film on glass (FOG).

(14) The planar shape of the liquid crystal panel 11 may be a vertically long rectangular shape, a square shape, a circular shape, a semi-circular shape, a vertically long elliptical shape, an oval shape, a trapezoidal shape, or the like.

(15) The display mode in the liquid crystal panel 11 may be any of a fringe field switching (FFS) mode, a twisted nematic (TN) mode, a vertical alignment (VA) mode, an in-plane switching (IPS) mode, or the like.

(16) Other than the liquid crystal panel 11, the display panel as the display device may be an organic electroluminescence (EL) display panel or a microcapsule-type electrophoretic (EPD) display panel.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A semiconductor device comprising:
a semiconductor portion constituted of a part of a semiconductor film;
a first insulating film disposed on an upper-layer side of the semiconductor film;
a first conductive portion disposed on an upper-layer side of the first insulating film and disposed not to overlap the semiconductor portion;
a second insulating film disposed on an upper-layer side of the first insulating film and the first conductive portion;
a second conductive portion disposed on an upper-layer side of the second insulating film and disposed to overlap the semiconductor portion; and
a third conductive portion disposed on an upper-layer side of the second insulating film and disposed to overlap the first conductive portion,
wherein the first insulating film and the second insulating film are provided with a first contact hole disposed to overlap both the semiconductor portion and the second conductive portion,
the second insulating film is provided with a second contact hole disposed to overlap both the first conductive portion and the third conductive portion,
the first conductive portion includes at least
a first conductive layer constituted of a part of the first conductive film disposed on the upper-layer side of the first insulating film,
a second conductive layer constituted of a part of the second conductive film disposed on the upper-layer side of the first conductive film, and
a sacrificial layer constituted of a part of a sacrificial film disposed on an upper-layer side of the second conductive film, and
the sacrificial layer is made of a semiconductor material or a conductive material, and includes a communication hole communicating with the second contact hole.

2. The semiconductor device according to claim 1,
wherein the sacrificial layer is made of an oxide semiconductor material that is the semiconductor material.

3. The semiconductor device according to claim 1,
wherein the sacrificial layer is made of a transparent electrode material that is the conductive material.

4. The semiconductor device according to claim 1,
wherein the first conductive layer includes aluminum, and the second conductive layer includes molybdenum.

5. The semiconductor device according to claim 1,
wherein a film thickness of the sacrificial layer is equal to 40 nm or less.

6. A display device comprising:
the semiconductor device according to claim 1; and
a counter substrate disposed to face the semiconductor device.

7. A manufacturing method of a semiconductor device comprising:
forming a semiconductor film, and patterning the formed semiconductor film to provide a semiconductor portion;
forming a first insulating film on an upper-layer side of the semiconductor film;
forming a first conductive portion including, in order from a lower-layer side, at least a first conductive layer constituted of a part of a first conductive film, a second conductive layer constituted of a part of a second conductive film, and a sacrificial layer constituted of a part of a sacrificial film at a position not overlapping the semiconductor portion by sequentially forming at least the first conductive film, the second conductive film, and the sacrificial film made of a semiconductor material or a conductive material each on an upper-layer side of the first insulating film and patterning the first conductive film, the second conductive film, and the sacrificial film;
forming a second insulating film on an upper-layer side of the first insulating film and the first conductive portion;
providing a part of a first contact hole at a position overlapping the semiconductor portion and a second contact hole at a position overlapping the first conductive portion by patterning the second insulating film;
providing a remaining portion of the first contact hole by patterning the first insulating film following the second insulating film;
cleaning a portion of the semiconductor portion facing the first contact hole and providing a communication hole communicating with the second contact hole in the sacrificial layer of the first conductive portion, by supplying a cleaning agent including hydrofluoric acid to the inside of the first contact hole and the second contact hole;
providing a second conductive portion on an upper-layer side of the second insulating film at a position overlapping the semiconductor portion, and connecting the second conductive portion to the semiconductor portion through the first contact hole; and
providing a third conductive portion on an upper-layer side of the second insulating film at a position overlapping the first conductive portion, and connecting the third conductive portion to the second conductive layer of the first conductive portion through the second contact hole and the communication hole.

8. The manufacturing method of a semiconductor device according to claim 7, further comprising:
forming the sacrificial film made of an oxide semiconductor material that is the semiconductor material; and
performing an annealing process after the first conductive portion is provided.
